(19) United States
(12) Patent Application Publication
(10) Pub. No.: US 2014/0079173 A1
(43) Pub. Date: Mar. 20, 2014

(54) SHIFTING REGISTER UNIT, SHIFTING REGISTER, DISPLAY APPARATUS AND DRIVING METHOD THEREOF

(71) Applicant: Yan YAN, Beijing (CN)

(72) Inventors: Yan Yan, Beijing (CN); Kun Cao, Beijing (CN)

(73) Assignees: BEIJING BOE DISPLAY TECHNOLOGY CO., LTD., Beijing (CN); BOE TECHNOLOGY GROUP CO., LTD., Beijing (CN)

(21) Appl. No.: 13/995,612

(22) PCT Filed: Dec. 20, 2012
(86) PCT No.: PCT/CN2012/086985

§ 371 Date: Jun. 19, 2013

(30) Foreign Application Priority Data
May 21, 2012 (CN) 201210159471.8

(51) Int. Cl. G11C 19/28

(52) U.S. Cl. CPC G11C 19/28
USPC 377/64

(57) ABSTRACT

The embodiments of the present invention provide a shifting register unit, a shifting register, a display apparatus and a driving method thereof, which can solve the problem that the displaying lines close to the bottom of a display panel can not operate normally due to the accumulation of the delays present in the existing shifting register unit and the problem that the lifespan of the third thin-film transistor is affected by the frequent switching-on thereof. The technical solutions allows the trigger signal of the (n+1)th shifting register unit stage to be provided by the first clock signal transmitted from the INPUT_NEXT terminal of the nth shifting register stage, and it can avoid the delay due to the trigger signal of the (n+1)th shifting register unit stage being provided by an output signal of the nth shifting register unit stage, and it can solve the technical problem that the display lines close to the bottom of the display panel can not operate normally due to the accumulation of the delays. Further, after the nth shifting register unit stage outputs the output signal and before the next input signal arrives, the pull-down node remains at high-level under the alternating control of the two clock signals. Thereby, it can be ensured that the pull-up node PU and the output terminal continue to be discharged, and thus the problem that the lifespan of the third thin-film transistor is affected by the frequent switching-on thereof can be solved.

### FIELD OF INVENTION

The present invention relates to a field of driving a display, and particularly relates to a shifting register unit, a shifting register, a display apparatus and a driving method thereof.

### BACKGROUND

Amorphous silicon Thin-Film Transistor integrated Gate Driver on Array (GOA) technology has been increasingly applied in the TFT-LCD manufacturing field, however, during the process of operation wherein the existing GOA driving circuit is triggered continuously, a trigger signal of the (n+1)th stage is commonly provided by the output signal of the nth stage. Thus the delay of the nth stage will be accumulated at the (n+1)th stage, so that a thin-film transistor in a GOA driving circuit, which carries output function, can not turn on normally, and thus the phenomena occurs that displaying lines close to the bottom in the vertical direction are unable to operate normally in a relatively high resolution TFT-LCD panel and a Dual Gate product. Furthermore, since thin-film transistors implementing the main output function are relatively large in size, the frequent switching-on causes the threshold voltage of thin-film transistors to drift, and therefore affects the lifespan thereof.

### SUMMARY

An embodiment of the present invention provides a shifting register unit, a shifting register, display apparatus and a driving method thereof, which can solve the problem that the displaying lines close to the bottom of a display panel can not operate normally due to the accumulation of the delays present in the existing shifting register unit and the problem that the lifespan of the third thin-film transistor is affected by the frequent switching-on thereof.

An embodiment of the present invention provides a shifting register unit, comprising:

a storage capacitor, having a terminal connected to a pull-up node, and another terminal connected to an output terminal;

a first thin-film transistor, for charging the pull-up node and the storage capacitor when an input signal is at high-level;

a reset module, for discharging the pull-up node and the storage capacitor under the control of a reset signal;

a third thin-film transistor, for sending an output signal to the output terminal when a first clock signal is at high-level;

an eighth thin-film transistor, for sending a trigger signal when the third thin-film transistor sends the output signal to the output terminal;

a potential maintaining module, for alternately controlling a pull-down node to be at high-level before an arrival of a next input signal according to the first clock signal and a second clock signal, which makes the pull-up node and the output terminal continue to be discharged.

According to an embodiment of the present invention, the reset module comprises:

a reset terminal;

a second thin-film transistor, having a gate connected to the reset terminal, a drain connected to the pull-up node, and a source connected to a low-level terminal; and

a fourth thin-film transistor, having a gate connected to the reset terminal, a drain connected to the output terminal, and a source connected to the low-level terminal.

According to an embodiment of the present invention, the potential maintaining module comprises:

a fifth thin-film transistor, having a drain and a gate connected to a second clock signal input terminal, and a source connected to the pull-down node;

a sixth thin-film transistor, having a drain connected to the pull-down node, a gate connected to one terminal of the storage capacitor, and a source connected to the low-level terminal;

a ninth thin-film transistor, having a drain and a gate connected to a first clock signal input terminal, and a source connected to the pull-down node;

a tenth thin-film transistor, having a drain connected to the pull-up node, a gate connected to the pull-down node, and a source connected to the low-level terminal; and

an eleventh thin-film transistor, having a drain connected to the output terminal, a gate connected to the pull-down node, and a source connected to the low-level terminal.

According to an embodiment of the present invention, a W/L value of the third thin-film transistor is greater than a W/L value of the eighth thin-film transistor.

An embodiment of the present invention further provides a shifting register, comprising a plurality of stages of shifting register units connected in cascade, wherein,

an output terminal of an nth shifting register unit stage is connected to a reset terminal of an (n−1)th shifting register unit stage;

an INPUT_NEXT terminal of the nth shifting register unit stage is connected to an input terminal of an (n+1)th shifting register unit stage.

An embodiment of the present invention further provides a display apparatus, comprising the above-mentioned shifting registers.

An embodiment of the present invention also provides a method for driving the above-mentioned shifting registers, comprising:

turning on the first thin-film transistor to charge the pull-up node, when a high level signal is received at the input terminal of the shifting register unit at the present stage;

turning on the third thin-film transistor to allow the output signal at the output terminal to be at high-level, when the first clock signal is at high-level;

in the next cycle of the clock signal, changing the reset signal to be at high-level to start discharging the pull-up node and the output terminal of the present stage, which makes the output terminal of the present stage be at low-level; and

thereafter, by the alternative control of the first clock signal and the second clock signal, remaining the output terminal of the present stage at low-level before the arrival of the next input signal.

The shifting register unit, shifting register, display apparatus and driving method thereof provided by the embodiments of the present invention allow the trigger signal of the (n+1)th shifting register unit stage to be provided by the first clock signal transmitted from the INPUT_NEXT terminal of the nth shifting register unit stage, and it can avoid the delay due to the trigger signal of the (n+1)th shifting register unit stage being provided by an output signal (OUTPUT signal) of the nth shifting register unit stage, and it can solve the technical problem that the display lines close to the bottom of the display panel can not operate normally due to the accumulation of the delays. Further, after the nth shifting register unit stage outputs the OUT signal and before the next input signal (INPUT signal) arrives, the pull-down node PD remains at high-level under the alternating control of the first clock signal and the second clock signal. Thereby, it can be ensured that the pull-up node PU (being directly connected to the gate of the third thin-film transistor) and the output terminal continue to be discharged, and thus the problem that the lifespan of the third thin-film transistor is affected by the frequent switching-on thereof can be solved.

### BRIEF DESCRIPTION OF THE DRAWINGS

FIG. 1 is a structure schematic diagram of a shifting register unit of an embodiment of the present invention;

FIG. 2 is a structure schematic diagram of a shifting register of an embodiment of the present invention;

FIG. 3 is timing chart of the shifting register unit of FIG. 2; and

FIG. 4 is an operating principal diagram of a display apparatus comprising the shifting register unit of FIG. 2.

### DETAILED DESCRIPTION

The following description will be made in connection with the accompanied drawings and detailed embodiments in order to make the technical problem to be solved by the embodiments of the present invention, the technical solutions and advantages thereof more clear.

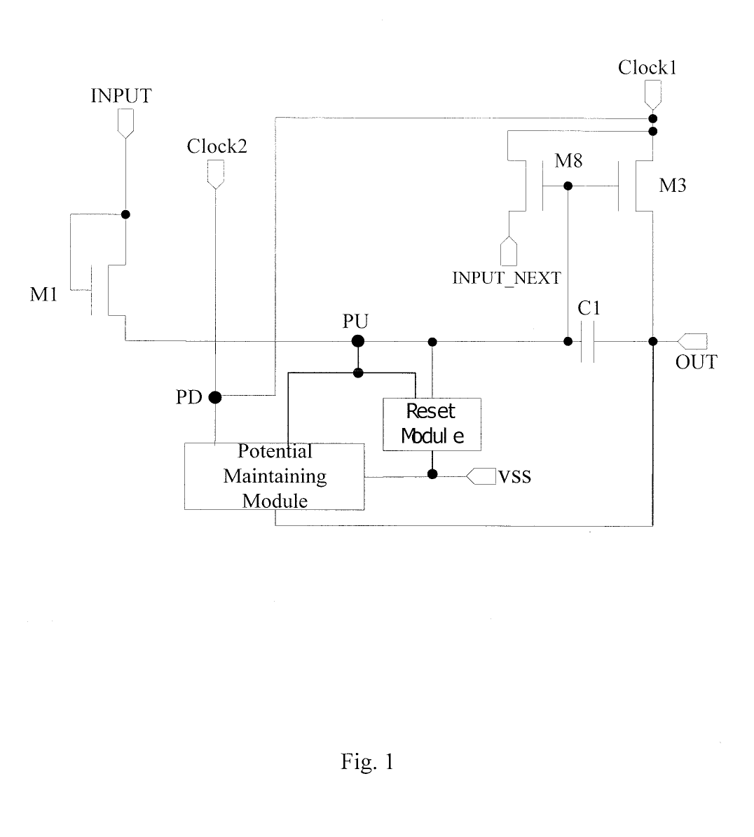

As shown in FIG. 1, an embodiment of the present invention provides a shifting register unit, comprising:

a first thin-film transistor M1, for charging a pull-up node PU and a storage capacitor C1 when an input signal INPUT is at high-level; wherein, the input signal INPUT of the present stage is input from an INPUT_NEXT terminal of the previous stage; preferably, a first clock signal Clock 1 is output to the INPUT_NEXT terminal via an eighth thin-film transistor M8 when the eighth thin-film transistor M8 switches on;

a reset module, for discharging the pull-up node PU and the storage capacitor C1 under the control of a reset signal;

a third thin-film transistor M3, for sending an output signal to the output terminal OUT when the first clock signal Clock1 is at high level;

the eighth thin-film transistor M8, for sending a trigger signal when the third thin-film transistor M3 sends the output signal to the output terminal OUT; and

a potential maintaining module, for alternately controlling a pull-down node PD to be at high level before an arrival of a next input signal according to the first clock signal Clock1 and a second clock signal Clock2, so that the pull-up node PU and the output terminal OUT continue to be discharged.

The shifting register unit provided by the embodiment of the present invention allows the trigger signal of the (n+1)th shifting register unit stage to be provided by the first clock signal transmitted from the INPUT_NEXT terminal of the nth stage, and it enables to avoid the delay brought by the fact that an OUT signal of the nth shifting register unit stage provides the trigger signal for the (n+1)th shifting register unit stage, and thus addresses the technical problem that the display lines close to the bottom of the display panel can not operate normally due to the accumulation of the delay. Further, after the nth shifting register unit stage outputs the OUT signal and before a next INPUT signal arrives, the pull-down node PD remains at high level under the alternating control of the first clock signal and the second clock signal. Thereby, it can ensure that the pull-up node PU (being directly connected to the gate of the third thin-film transistor M3) and the output terminal continue to be discharged, and thus it can solve the problem that the lifespan of the thin third thin-film transistor M3 is affected by the frequent switching-on thereof.

There is a significant delay when the trigger signal is provided to the (n+1)th shifting register unit stage from the third thin-film transistor M3, while there is a much less delay when it is provided from the eighth thin-film transistor M8. The two main reasons behind are as follows:

Firstly, in the design, the W/L (the ratio of width to length of the channel of a transistor) value of the third thin-film transistor M3 is much greater than the W/L value of the eighth thin-film transistor M8, and therefore, the attenuation degrees of the same CLK signal after passing through one of these two transistors respectively are different from each other.

Secondly, there is a large load connected to the output terminal of the third thin-film transistor M3 (e.g. there is a Gate Line Load when the output terminal of the third thin film transistor M3 is connected to the gate lines of a display apparatus when it is connected to the display apparatus), which has an influence on the output signal. While, there is no large load connected to the output terminal of the eighth thin-film transistor M8, and therefore there is a difference between the output signals under the two cases.

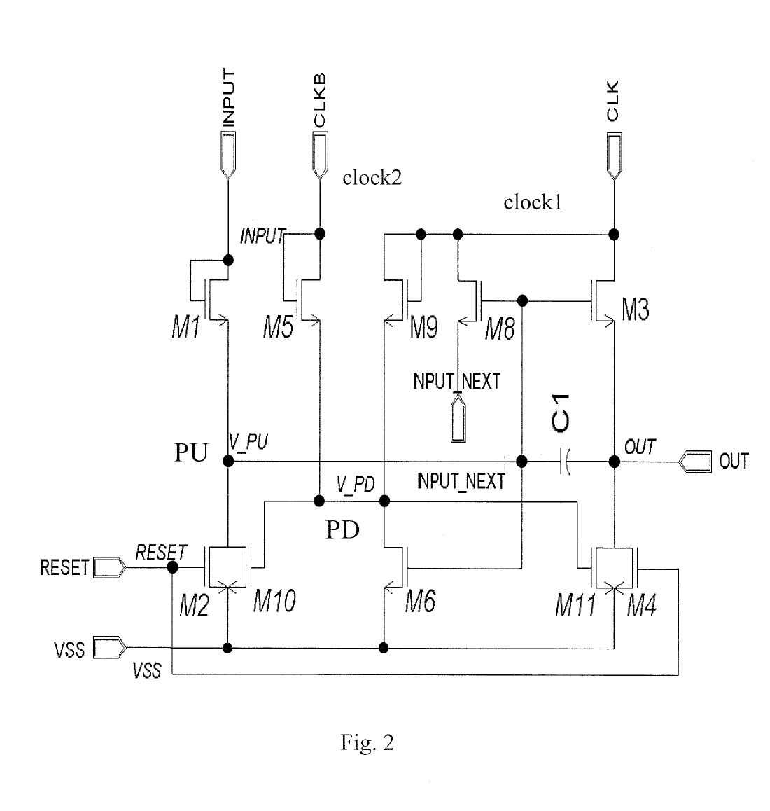

As shown in FIG. 2, the above-mentioned reset module comprises:

a reset terminal RESET;

a second thin-film transistor M2, having a gate connected to the reset terminal RESET, a drain connected to the pull-up node PU, and a source connected to a low-level VSS; and

a fourth thin-film transistor M4, having a gate connected to the reset terminal RESET, a drain connected to the output terminal OUT, and a source connected to the low-level VSS.

Again, as shown in FIG. 2, the potential maintaining module can comprise:

a fifth thin-film transistor M5, having a drain and a gate connected to a second clock signal input terminal CLKB, and a source connected to the pull-down node PD;

a sixth thin-film transistor M6, having a drain connected to the pull-down node PD, a gate connected to one terminal of the storage capacitor C1, and a source connected to the low-level VSS;

a ninth thin-film transistor M9, having a drain and a gate connected to a first clock signal input terminal CLK, and a source connected to the pull-down node PD;

a tenth thin-film transistor M10, having a drain connected to the pull-up node PU, a gate connected to the pull-down node PD, and a source connected to the low-level VSS; and

an eleventh thin-film transistor M11, having a drain connected to the output terminal OUT, a gate connected to the pull-down node PD, and a source connected to the low level VSS.

The functions of the above individual transistors will be described as follows:

The first thin-film transistor M1 charges the pull-up node PU, and charges the storage capacitor C1 at the same time, wherein the switching-on and triggering for the input terminal of the present stage are provided from the INPUT_NEXT terminal of the previous stage.

The second thin-film transistor M2 discharges the pull-up node PU, wherein the second thin-film transistor M2 is switched on by a switching-on signal provided from the output terminal (OUT terminal) at the next stage to the RESET terminal at the present stage, and it is pulled down by the low-level VSS directly.

The third thin-film transistor M3 provides a high-level output signal (if being applied in a display apparatus, i.e., the TFT gate switching-on signal in the active matrix of the display apparatus) to the output terminal at the present stage, when the first clock signal Clock1 is at high-level.

The fourth thin-film transistor M4 discharges the output terminal OUT at the present stage. The fourth thin-film transistor M4 is switched on by a switching-on signal provided from the output terminal at the next stage to the RESET terminal at the present stage, and it is pulled down by the low-level VSS directly.

The fifth thin-film transistor M5 charges the pull-down node PD when the second clock signal Clock2 is at high-level, and further turns on the tenth thin-film transistor M10 and the eleventh thin-film transistor M11, so as to ensure that the pull-up node PU and the output terminal OUT continue to be discharged when the present stage is at a non-output phase.

The sixth thin-film transistor M6 is controlled by the potential of the pull-up node PU, and further controls the potential of the pull-down node PD, so as to ensure that the tenth thin-film transistor M10 and the eleventh thin-film transistor M11 are turned off in the charging and outputting phases; and in the non-charging and outputting phases, the tenth thin-film transistor M10 and the eleventh thin-film transistor M11 switch on when the first clock signal Clock1 is at high-level, and continue to discharge the pull-up node PU and the output terminal OUT.

The eighth thin-film transistor M8 provides a trigger signal to the INPUT TERMINAL at the next stage when the pull-up node PU is at high-level and the first clock signal Clock1 is at high-level (i.e. when the present stage outputs).

The ninth thin-film transistor M9 in cooperation with the first clock signal Clock1 controls the potential of the pull-down node PD, so as to ensure that the pull-up node PU and the output terminal OUT continue to be discharged when the present stage is in the non-outputting phase.

The tenth thin-film transistor M10 and the eleventh thin-film transistor M11 discharge the pull-up node PU and the output terminal OUT respectively.

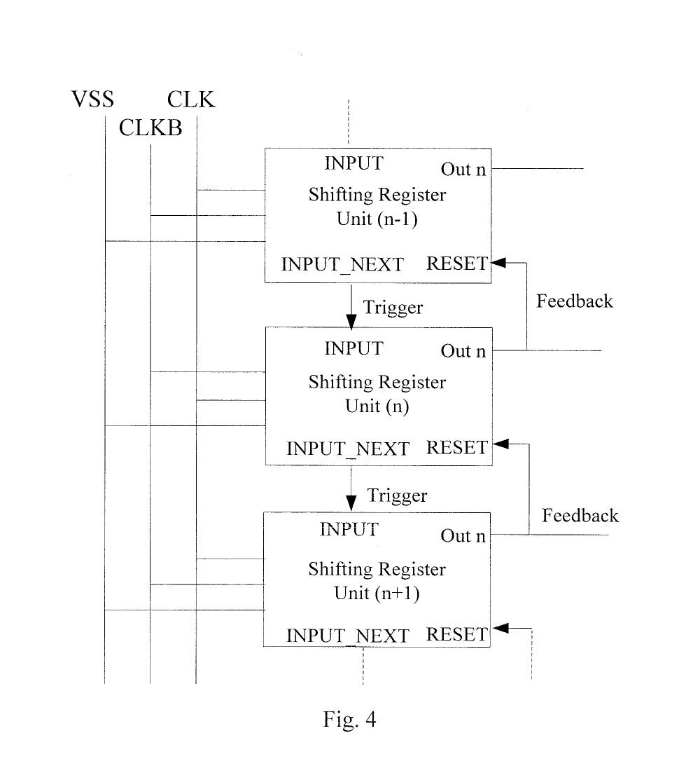

As shown in FIG. 4, an embodiment of the present invention further provides a shifting register, comprising a plurality of stages of the above-mentioned shifting register units connected in cascade, wherein,

an output terminal (OUT terminal) of the nth shifting register unit stage is connected to a reset terminal (RESET terminal) of the (n−1)th shifting register unit stage for providing a feedback signal thereto; and

an INPUT_NEXT terminal of the nth shifting register unit stage is connected to an input terminal (INPUT terminal) of the (n+1)th shifting register unit stage for providing a trigger signal thereto,

wherein, n is a positive integer equal to or greater than 2.

In the shifting register provided by embodiment of the present invention, the traditional Gate Driver IC is replaced by the shifting register unit provided in the embodiment of the present invention in the repeating array and sequential connection. The function of shifting register is implemented by configuration of signals, and the switching-on signal is provided from the output terminal (OUT terminal) of shifting register unit to the gate of the TFT in the display panel for turning the TFT on, and thus it is possible to drive a panel in a progressive scanning manner from top to bottom.

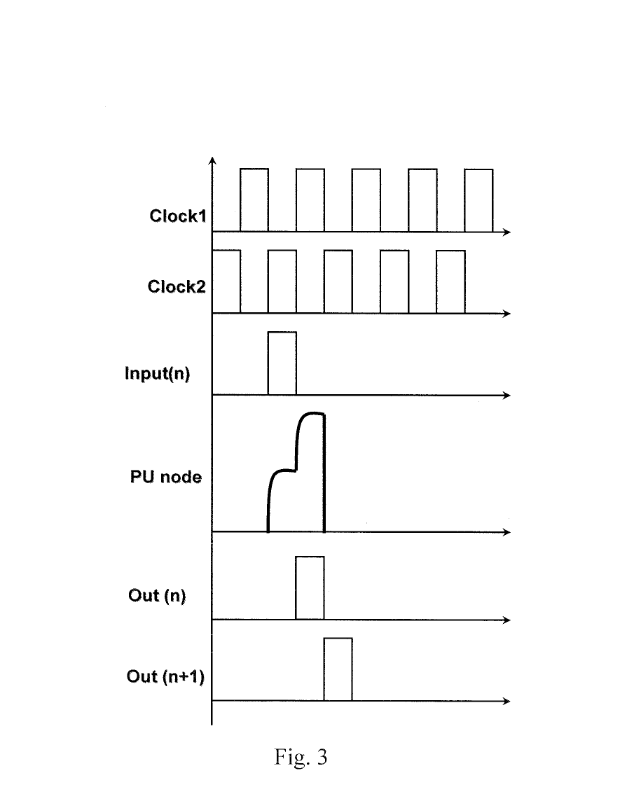

In connection with FIGS. 3 and 4, the operating principle of the shifting register as shown in FIG. 2 is described as follows:

The output terminal of the eighth thin-film transistor M8 in the (n−1)th shifting register unit stage is connected to the input terminal (INPUT terminal) of the nth shifting register unit stage, and the output terminal of the (n+1)th shifting register unit stage is connected to the RESET terminal of the nth shifting register unit stage. When the (n−1)th shifting register unit stage outputs, i.e. when the INPUT signal of the nth shifting register unit stage is at high-level: the first thin-film transistor M1 switches on, and charges the pull-up node PU; when the first clock signal Clock1 is at high-level, the third thin-film transistor M3 switches on, the output terminal OUT outputs a pulse of the first clock signal Clock1; meanwhile, the potential of the pull-up node PU is further pulled up under the bootstrap effect of the storage capacitor C1; thereafter, the reset terminal RESET is at high-level, the second thin-film transistor M2 and the fourth thin-film transistor M4 are switched on, and the pull-up node PU and the output terminal OUT are discharged; next, the potential of the pull-down node PD is alternately controlled by the first clock signal Clock1 and the second clock signal Clock1, so that the pull-up node PU and the output terminal OUT continue to be discharged to avoid the node PU being in a floating state, ensuring that no noise will occur when the present stage is in the non-operation time.

Further, an embodiment of the present invention further provides a display apparatus, comprising a plurality of shifting registers provided by embodiments of the present invention.

An embodiment of the present invention further provides a driving method for the above-mentioned shilling registers, comprising:

inputting a trigger signal to an input terminal of the nth shifting register unit stage by the eighth thin-film transistor M8 in the (n−1)th shifting register unit stage; inputting an output signal of the (n+1)th shifting register unit stage from the (n+1)th shifting register unit stage to a reset module of the nth shifting register unit stage as a reset signal;

wherein, when the trigger signal received at the input terminal of the nth shifting register unit stage is at high-level, a first thin-film transistor M1 switches on and charges the pull-up node PU;

when a first clock signal is at high-level, a third thin-film transistor M3 switches on, the output terminal outputs a pulse of the first clock signal, and the output signal at the output terminal is at high-level; meanwhile, the pull-up node PU is further pulled up under the bootstrap effect of the storage capacitor C1;

in the next cycle of the clock signal, the reset signal is at high level, and it begins to discharge the pull-up node PU and the output terminal OUTPUT of the present stage to make the output terminal of the present stage be at low-level; thereafter, according to the first clock signal Clock1 and the second clock signal Clock2, the pull-down node PD of the present stage is alternately controlled to be at high-level before the arrival of the next input signal, so that the pull-up node PU and the output terminal OUT of the present stage continue to be discharged before the arrival of the next input signal and thus both are in a low-level state.

The above-mentioned driving method provided by the embodiments of the present invention allows the trigger signal of the nth shifting register unit stage to be provided by the first clock signal transmitted from the INPUT_NEXT terminal of the (n−1)th shifting register stage, and it can avoid the delay due to the trigger signal of the nth shifting register unit stage being provided by an OUT signal of the (n−1)th shifting register unit stage, and it can solve the technical problem that the display lines close to the bottom of the display panel can not operate normally due to the accumulation of the delays. Further, after the nth shifting register unit stage outputs the OUT signal and before the next INPUT signal arrives, the pull-down node PD remains at high-level under the alternating control of the first clock signal and the second clock signal. Thereby, it can be ensured that the pull-up node PU (being directly connected to the gate of the third thin-film transistor M3) and the output terminal continue to be discharged, and thus the problem that the lifespan of the third thin-film transistor M3 is affected by the frequent switching-on thereof can be solved.

The above are preferred implementations of the present invention. It should be noted that, various changes and modifications can be made to the present invention by those ordinary skilled in the art without departing from the principle of the present invention, and those changes and modifications shall be deemed as within the protection scope of the present invention.

1. A shifting register unit, comprising:
a storage capacitor, having a terminal connected to a pull-up node, and another terminal connected to an output terminal;
a first thin-film transistor, for charging the pull-up node and the storage capacitor when an input signal is at high-level;
a reset module, for discharging the pull-up node and the storage capacitor under the control of a reset signal;
a third thin-film transistor, for sending an output signal to the output terminal when a first clock signal is at high-level;
an eighth thin-film transistor, for sending a trigger signal when the third thin-film transistor sends the output signal to the output terminal; and
a potential maintaining module, for alternately controlling a pull-down node to be at high-level before an arrival of a next input signal according to the first clock signal and a second clock signal, to make the pull-up node and the output terminal continue to be discharged.

2. The shifting register unit according to claim 1, wherein, the reset module comprises:
a reset terminal;
a second thin-film transistor, having a gate connected to the reset terminal, a drain connected to the pull-up node, and a source connected to a low-level terminal; and
a fourth thin-film transistor, having a gate connected to the reset terminal, a drain connected to the output terminal, and a source connected to the low-level terminal.

3. The shifting register unit according to claim 1, wherein, the potential maintaining module comprises:
a fifth thin-film transistor, having a drain and a gate connected to a second clock signal input terminal, and a source connected to the pull-down node;
a sixth thin-film transistor, having a drain connected to the pull-down node, a gate connected to a terminal of the capacitor, and a source connected to the low-level terminal;
a ninth thin-film transistor, having a drain and a gate connected to a first clock signal input terminal, and a source connected to the pull-down node;
a tenth thin-film transistor, having a drain connected to the pull-up node, a gate connected to the pull-down node, and a source connected to the low-level terminal; and
an eleventh thin-film transistor, having a drain connected to the output terminal, a gate connected to the pull-down node, and a source connected to the low-level terminal.

4. The shifting register unit according to claim 1, wherein a W/L value of the third thin-film transistor is greater than a W/L value of the eighth thin-film transistor.

5. A shifting register, comprising a plurality of stages of the shifting register units connected in cascade according to claim 1, wherein,
an output terminal of an nth shifting register unit stage is connected to a reset terminal of an (n−1)th shifting register unit stage; and
an INPUT_NEXT terminal of the nth shifting register unit stage is connected to an input terminal of an (n+1)th shifting register unit stage.

6. (canceled)

7. A method for driving the shifting register according to claim 5 comprising the steps of:
turning on the first thin-film transistor to charge the pull-up node, when a high level signal is received at the input terminal of the shifting register unit at the present stage;
turning on the third thin-film transistor to allow the output signal at the output terminal to be at high-level, when the first clock signal is at high-level;
in a next cycle of the clock signal, changing the reset signal to be at high-level to start discharging the pull-up node and the output terminal of the present stage, to make the output terminal of the present stage be at low-level; and
thereafter, by the alternative control of the first clock signal and the second clock signal, remaining the output terminal of the present stage at low-level before an arrival of a next input signal.

8. The shifting register unit according to claim 5, wherein the reset module comprises:
a reset terminal;
a second thin-film transistor having a gate connected to the reset terminal, a drain connected to the pull-up node, and a source connected to the low-level terminal; and
a fourth thin-film transistor having a gate connected to the reset terminal, a drain connected to the output terminal, and a source connected to the low-level terminal.

9. The shifting register unit according to claim 5, wherein the potential maintaining module comprises:
a fifth thin-film transistor having a drain and a gate connected to a second clock signal input terminal, and a source connected to the pull-down node;
a sixth thin-film transistor having a drain connected to the pull-down node, a gate connected to a terminal of the capacitor, and a source connected to the low-level terminal;
a ninth thin-film transistor having a drain and a gate connected to a first clock signal input terminal, and a source connected to the pull-down node;
a tenth thin-film transistor having a drain connected to the pull-up node, a gate connected to the pull-down node, and a source connected to the low-level terminal; and
an eleventh thin-film transistor having a drain connected to the output terminal, a gate connected to the pull-down node, and a source connected to the low-level terminal.

10. The shifting register unit according to claim 5, wherein a W/L value of the third thin-film transistor is greater than a W/L value of the eighth thin-film transistor.
